(19) United States
(12) Patent Application Publication
(10) Pub. No.: US 2012/0228683 A1
(43) Pub. Date: Sep. 13, 2012

(54) SPIN DEVICE, AND MAGNETIC SENSOR AND SPIN FET USING THE SAME

(75) Inventors: Tohru OIKAWA, Tokyo (JP); Tomoyuki SASAKI, Tokyo (JP); Yoshitomo TANAKA, Tokyo (JP); Kiyoshi NOGUCHI, Tokyo (JP)

(73) Assignee: TDK CORPORATION, Tokyo (JP)

(21) Appl. No.: 13/416,574

(22) Filed: Mar. 9, 2012

(30) Foreign Application Priority Data
Mar. 11, 2011 (JP) 2011-054564

(51) Int. Cl. H01L 29/82

(52) U.S. Cl. 257/295; 257/421; 257/E29.323

(57) ABSTRACT

This spin device includes a semiconductor layer 3 formed of single crystalline Si, a first tunnel insulating layer T1 formed on a surface of the semiconductor layer 3, and a first ferromagnetic metal layer 1 formed on the first tunnel insulating layer T1. Area density of dangling bonds in an interface between the semiconductor layer 3 and the first tunnel insulating layer T1 is 3×10¹⁴/cm² or less. In this case, a polarization rate can be greatly improved.

### BACKGROUND OF THE INVENTION

1. Field of the Invention

The present invention relates to a spin device, and a magnetic sensor and a spin field effect transistor (FET) using the same.

2. Related Background Art

In recent years, a spin electronics device using both functionality of spin in a ferromagnetic material and functionality of electrons in electrical conduction has been actively studied and developed. An example of such a device includes a magnetic head in a hard disk drive or an MRAM (Magnetic Random Access Memory). In addition, an idea of a spin MOS-FET in which a MOS-FET (Metal-Oxide-Semiconductor-Field-Effect Transistor) has functionality of spin has been proposed and a semiconductor (silicon) spin electronic device has also been actively studied and developed.

Basic technology for such spin electronics is use of spin injection from a metal ferromagnetic material to a non-magnetic material. A magnetic memory and a magnetic sensor using a metal as the non-magnetic material are also disclosed (Patent Document 1 (Japanese Patent Application Laid-open No. 2004-186274) and Patent Document 2 (Japanese Patent Application Laid-open No. 2007-299467)).

Also, a spin MOSFET using Si as the non-magnetic material is disclosed (Patent Document 3 (Japanese Patent Application Laid-open No. 2004-11904)). In order to increase efficiency of the spin injection, a ferromagnetic metal/tunnel insulating film/non-magnetic material is employed as an electrode structure, spin injected to the non-magnetic material is conducted (a conduction layer in this case will be referred to as a channel), and the conducted spin is detected from a change in a potential according to a magnetization direction at facing electrodes having the same structure. In the case of a semiconductor, a Schottky barrier formed in an interface can be used as a pseudo-tunnel layer, instead of the tunnel insulating film.

Device applications may be classified into a non-local structure (Patent Documents 1 and 2) and a local structure (Patent Document 3). In the non-local structure, since current passing through a fixed layer does not flow into a free layer, current in a channel region between the fixed layer and the free layer is zero and only a finite spin flow flows. That is, since an electron flow by up-spin and an electron flow by down-spin are the same in magnitude and reverse in direction, the flows are completely cancelled. Part of the spin flow diffusing to the channel region is absorbed in a magnetic material of the free layer. In this case, since a potential of the free layer is changed with a relative magnetization direction of the free layer and the fixed layer, the potential can be measured using a voltage meter. Thus, in terms of a spin conduction form, in the non-local structure, the spin flow rather than the electron flow carries spin information. In the spin flow, noise caused by anisotropic magnetoresistance (AMR), Joule heat or the like is very small, and it is suitable for high-quality spin information transfer. In the local structure, spin information is conducted using spin-polarized current as a carrier, as in a conventional magnetoresistance device.

Use of an electron flow as an input, a spin flow as information transfer, and a spin accumulation voltage as an output is common to a basic operation of all devices with spin injection. Accordingly, a determination as to whether or not a device operation is good is based on how effectively the flow of spin is created from current. When an injection electron flow is i and spin components of current when the current is input from an injection electrode to a channel are i₍ᵤₚ₎ and i_{(down)}, the injection electron flow is given as i=(i₍ᵤₚ₎+I_{(down)}). However, the height at which a spin polarization rate P can be set is important. The spin polarization rate P is given as the following equation:

Spin polarization rate P=(i₍ᵤₚ₎−i_{(down)})/i (Equation 1)

In the ferromagnetic material, ease of flow of the current varies with the spin direction of the electrons, and electric conductivity σ₍ᵤₚ₎ of the up-spin differs from electric conductivity σ_{(down)} of the down-spin. Accordingly, current flowing in the ferromagnetic material is spin polarized and its polarization rate P_{F} is as follows:

Spin polarization rate P_{F} in ferromagnetic material=(σ₍ᵤₚ₎−σ_{(down)})/(σ₍ᵤₚ₎+σ_{(down)}) (Equation 2)

Accordingly, if there is no electron scattering inside the electrode, the spin polarization rate P of the injected electron flow is expected to be the spin polarization rate P_{F} in the ferromagnetic material. When the tunnel film is single crystal and has a spin filter effect, P may theoretically be greater than or equal to P_{F}.

However, an actual polarization rate P is much smaller than the polarization rate P_{F} in the ferromagnetic material. According to the study of the present inventors, it has been found that electron scattering occurs in an interface between a tunnel film and Si and the polarization rate P is reduced (Non-Patent Document 1 (T. Sasaki et al. Applied Physics Letter, 96, 122101, 2010) and Non-Patent Document 2 (T. Sasaki et al. APEX, 2, 053003, 2009)).

According to Non-Patent Document 1, the polarization rate P at 8K is about 0.02. As a temperature increases, the polarization rate P decreases, The polarization rate P is 0.01 or less at 100K or more. Since the spin polarization rate P_{F} of Fe used as a ferromagnetic material is about 0.5, the actual polarization rate P decreases to 4% or less of P_{F}.

In order to reduce interfacial scattering, epitaxial growth of a tunnel film and a ferromagnetic metal on Si has been attempted. For example, the growth of MgO as the tunnel film and Fe as the ferromagnetic metal has been attempted. However, the result that a Si interface becomes amorphous has been reported (Non-Patent Document 3 (C. Martinez et al. 3, Appl. Phys. Vol. 93, 2126, 2003)).

### SUMMARY OF THE INVENTION

However, in the related art, a solution for improving a polarization rate has not been found. The present invention has been made in view of such a problem, and an object of the present invention is to provide a spin device, and a magnetic sensor and a spin FET using the same capable of improving the polarization rate.

In a tunnel magnetoresistance effect device, it may be preferable that a material of a tunnel insulating layer be single crystalline rather than amorphous in order to obtain a high polarization rate. Therefore, the present inventors have attempted epitaxial growth of the tunnel insulating layer on a semiconductor layer formed of Si. As a result, the present inventors have found from their intensive study that there are a number of dangling bonds between the Si semiconductor layer and the tunnel insulating layer, and the polarization rate can be greatly improved by reducing the density of the dangling bonds.

That is an aspect of the present invention is a spin device including: a semiconductor layer formed of single crystalline Si; a first tunnel insulating layer formed on a surface of the semiconductor layer, the first tunnel insulating layer being crystalline; and a first ferromagnetic metal layer formed on the first tunnel insulating layer, wherein a surface or area density of dangling bonds in an interface between the semiconductor layer and the first tunnel insulating layer is 3×10¹⁴/cm² or less. When electrons are injected from the first ferromagnetic metal layer into the semiconductor layer via the first tunnel insulating layer, spin dependent on a magnetization direction of the first ferromagnetic metal layer is injected into the semiconductor layer. In this case, a polarization rate can be greatly improved when the area density of the dangling bonds has the above value. This polarization rate is similarly improved even when spin is injected from the semiconductor layer into the first ferromagnetic metal layer via the first tunnel insulating layer.

When the area density of the dangling bonds was 1×10¹⁴/cm² or more, the above-described effect of improvement of the polarization rate could be confirmed.

It is preferable that the first tunnel insulating layer be MgO. When single crystalline Si was used as the semiconductor layer and MgO was used as the tunnel insulating layer, the polarization rate of 10% or more was obtained.

A magnetic sensor according to an aspect of the present invention includes the above-described spin device; a second tunnel insulating layer formed on a surface of the semiconductor layer; a second ferromagnetic metal layer formed on the second tunnel insulating layer; and a pair of electrodes formed of a non-magnetic metal on the semiconductor layer. In this case, since a spin polarization rate is high, high-accuracy detection can be performed.

A spin. FET according to an aspect of the present invention includes the above-described spin device; a second tunnel insulating layer formed on a surface of the semiconductor layer; a second ferromagnetic metal layer formed on the second tunnel insulating layer; and a gate electrode for controlling a potential of the semiconductor layer between the first and second ferromagnetic metal layers. In this case, since a spin polarization rate is high, a high-accuracy operation can be performed.

According to the spin device of an aspect of the present invention, it is possible to improve a polarization rate. Accordingly, a magnetic sensor and a spin FET using the spin device are capable of performing high-accuracy detection or operation.

### BRIEF DESCRIPTION OF THE DRAWINGS

FIG. 1 is a diagram showing a longitudinal cross-sectional configuration of a spin device in a non-local, structure;

FIGS. 2A and 2B are XZ cross-sectional views in positions of ferromagnetic metal layers 1 and 2 of the spin device shown in FIG. 1, respectively;

FIGS. 3A and 3B are diagrams showing detailed electrode structures including the ferromagnetic metal layers 1 and 2;

FIG. 4 is a diagram showing an inverse Fourier TEM image of an Fe/MgO/Si stack (Comparative example);

FIG. 5 is a diagram showing an inverse Fourier TEM image of an Fe/MgO/Si stack (Example);

FIG. 6 is a graph showing an ESR spectrum (Comparative example);

FIG. 7 is a graph showing an ESR spectrum (Example);

FIG. 8 is a graph showing a relationship between area density DD(×10¹⁴/cm²) of dangling bonds and a spin polarization rate P;

FIG. 9 is a table showing area density DD (×10¹⁴/cm²) of dangling bonds, a spin polarization rate P, an annealing temperature (° C.), and presence or absence of spin conduction at room temperature;

FIG. 10 is a diagram showing a longitudinal cross-sectional structure of a magnetic head including a spin device 20 as a magnetic sensor; and

FIG. 11 is a diagram showing a longitudinal cross-sectional structure of a PET including a spin device.

### DESCRIPTION OF THE PREFERRED EMBODIMENTS

Hereinafter, a spin device according to an embodiment will be described. The same reference numerals are given to the same elements, and the duplicate explanation thereof will be omitted.

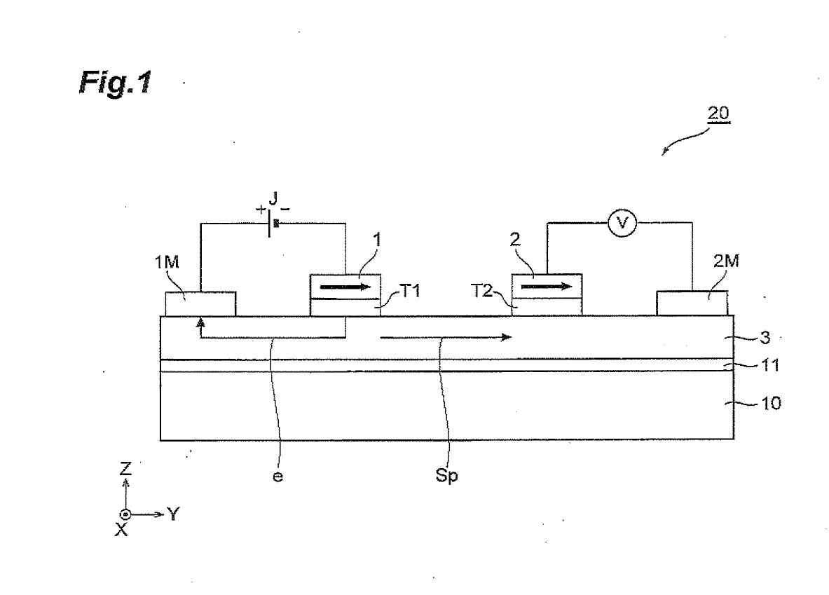

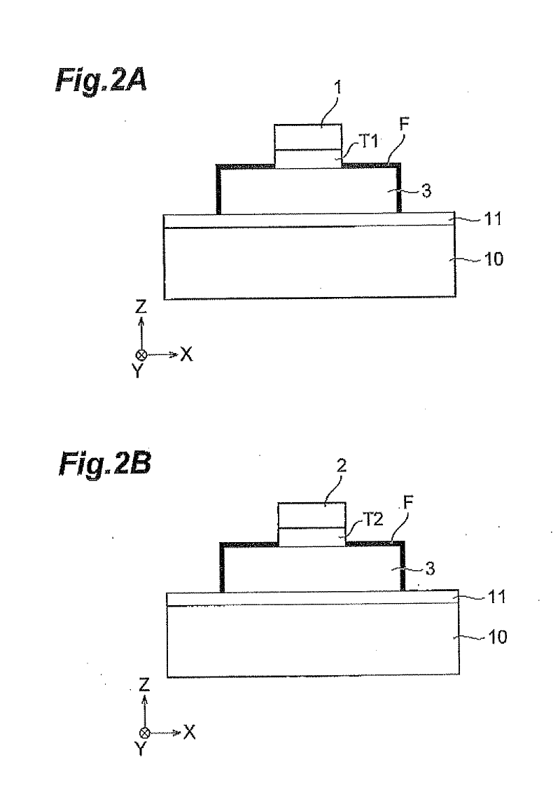

FIG. 1 is a diagram showing a longitudinal cross-sectional configuration of a spin device in a non-local structure. In FIG. 1, an XYZ three-dimensional Cartesian coordinate system is set. FIG. 2A is an XZ cross-sectional view in a position of a ferromagnetic metal layer 1 of the spin device shown in FIG. 1, and FIG. 2B is an XZ cross-sectional view in a position of a ferromagnetic metal layer 2 of the spin device.

A semiconductor layer 3 is formed on a semiconductor substrate 10 formed of Si via an insulating layer 11 of for example, SiO₂ or Al₂O₃. That is, a substrate including the semiconductor layer 3 is an SOI (Silicon-on-Insulator) substrate, and a thickness of the semiconductor layer 3 is set to, for example, 100 inn or less. When the SOI substrate is used, the semiconductor layer 3 can be thin. Accordingly, there is an advantage in that influence from a deep position of the substrate can be suppressed. The semiconductor layer 3 is formed of single crystalline Si, and a surface on which the ferromagnetic metal layers 1 and 2 and non-magnetic electrodes 1M and 2M are formed is {100}.

This spin device 20 includes the semiconductor layer 3 formed of single crystalline Si, a first tunnel insulating layer T1 formed on a surface of the semiconductor layer 3, and the first ferromagnetic metal layer 1 formed on the first tunnel insulating layer T1. Here, area density of dangling bonds in an interface between the semiconductor layer 3 and the first tunnel insulating layer T1 is 3×10¹⁴/cm² or less. In this case, a polarization rate can be greatly improved.

An electron flow source J is connected between the first ferromagnetic metal layer 1 and the first electrode 1M, When electrons are injected from the first ferromagnetic metal layer 1 to the semiconductor layer 3 via the first tunnel insulating layer T1 by the electron flow source J, spin dependent on a magnetization direction of the first ferromagnetic metal layer 1 is injected into the semiconductor layer. In this case, the polarization rate can be greatly improved when the area density of dangling bonds has the above value.

The spin device 20 shown in FIG. 1 can be caused to function as a magnetic sensor. That is, this magnetic sensor includes the second tunnel insulating layer T2 formed on the surface of the semiconductor layer 3, and the second ferromagnetic metal layer 2 formed on the second tunnel insulating layer T2. A pair of electrodes 1M and 2M formed of a non-magnetic metal is formed on the semiconductor layer 3. This magnetic sensor has a non-local structure, and electrons are supplied from the electron flow source J to the first ferromagnetic metal layer 1. The electrons e injected from the first ferromagnetic metal layer 1 into the semiconductor layer 3 are propagated through the inside of the semiconductor layer 3 and flow into the first electrode 1M.

Meanwhile, a spin flow Sp diffuses from a position of the injection electron from the first ferromagnetic metal layer 1 into the semiconductor layer 3, in a direction of the second ferromagnetic metal layer 2. According to the spin flow Sp, a voltage is generated between the second ferromagnetic metal layer 2 and the second electrode 2M, and is measured by a voltage meter V connected between the second ferromagnetic metal layer 2 and the second electrode 2M. In the spin flow Sp, a spin direction rotates depending on an external magnetic field introduced into the semiconductor layer 3, and the voltage value detected by the voltage meter V varies with a size of the magnetic field. Therefore, this spin device can be caused to function as a magnetic sensor.

Both the first and second ferromagnetic metal layers 1 and 2 have magnetization directions parallel to the Y axis. The magnetization directions are fixed and the first and second ferromagnetic metal layers 1 and 2 function as magnetization fixed layers. However, a structure in which the magnetization direction of one of the ferromagnetic metal layers is not fixed and the ferromagnetic metal layer is used as a free layer, as in a spin FET (field effect transistor), may be considered.

An aspect of the present invention may be applied to a magnetoresistance effect spin device rather than the spin device in the non-local structure. In this case, the following is used: an electron flow flows between the first ferromagnetic metal layer 1 and the second ferromagnetic metal layer 2, an amount of spin accumulated in an interface of the second ferromagnetic metal layer 2 is changed according to rotation of magnetization of the second ferromagnetic metal layer 2 or rotation of conducted spin due to an external magnetic field, and magnetoresistance is changed. The first and second electrodes 1M and 2M are assumed not to be used or not to be formed in advance. Resistance between the first ferromagnetic metal layer 1 and the second ferromagnetic metal layer 2 may be obtained by measuring current flowing therebetween when a certain voltage is applied. In the case of a non-local structure, it is preferable that the magnetization directions of the first and second ferromagnetic metal layers be the same directions (parallel) since a magnetic field applying process in fabrication is simplified. In the magnetoresistance effect type, it is preferable to have a structure in which the magnetization direction of one of the ferromagnetic metal layers is not fixed and the ferromagnetic metal layer is used as a free layer or it is preferable that the ferromagnetic metal layer is fixed in an anti-parallel manner from a viewpoint of acquisition of high output, as in a spin FET (field effect transistor).

The semiconductor layer 3 has a rectangular shape extending in a axis direction in which a portion other than a region functioning as a channel layer through which the election flow or the spin flow is propagated is removed by etching (see FIGS. 2A and 2B). Side surfaces and an exposed surface orthogonal to the Z axis of the semiconductor layer 3 exposed by etching are coated with an insulating protection film F such as SiO₂, as shown in FIGS. 2A and 2B.

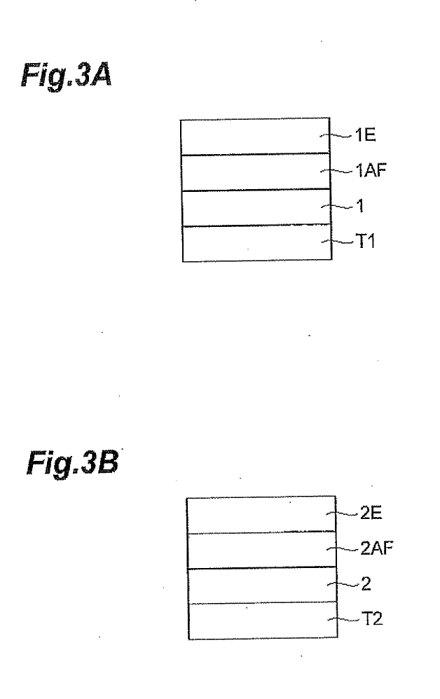

FIGS. 3A and 3B are diagrams showing detailed electrode structures including the ferromagnetic metal layers 1 and 2.

When a magnetization direction is fixed, the first ferromagnetic metal layer 1, a first antiferromagnetic layer 1AF, and a first electrode layer 1E connected with an external wiring are sequentially stacked on the first tunnel insulating layer T1, as shown in FIG. 3A. Similarly, when a magnetization direction is fixed, the second ferromagnetic metal layer 2, a second antiferromagnetic layer 2AF, and a second electrode layer 2E connected with an external wiring are sequentially stacked on the second tunnel insulating layer T2, as shown in FIG. 3B. The magnetization direction is fixed by exchange-bonding the ferromagnetic metal layers 1 and 2 and the antiferromagnetic layers 1AF and 2AF. When the ferromagnetic metal layer is caused to function as a free layer, a tendency of the magnetization direction to be easily directed to a longitudinal direction can be suppressed by not using the antiferromagnetic layer and reducing an aspect ratio of the ferromagnetic metal layer.

ZnO, Al₂O₃ or the like, as well as crystalline (single crystalline or polycrystalline, rather than amorphous) MgO, may be used as materials of the tunnel insulating films T1 and T2. Thicknesses of the tunnel insulating films T1 and T2 are preferably set to 2 nm or less for tunneling of electrons. Fe, Ni, Co, or an alloy such as CoFe or NiFe selected therefrom may be used as materials of the ferromagnetic metal layers 1 and 2. A Mn alloy such as IrMn or PtMn may be used as a material of the antiferromagnetic layers AF1 and AF2, When shape magnetic anisotropy is strong, the antiferromagnetic layers AF1 and AF2 may be omitted. Non-magnetic metals may be used as materials of the electrode layers 1E and 2E and the electrodes 1M and 2M. For example, Al, Cu, or Au may be used.

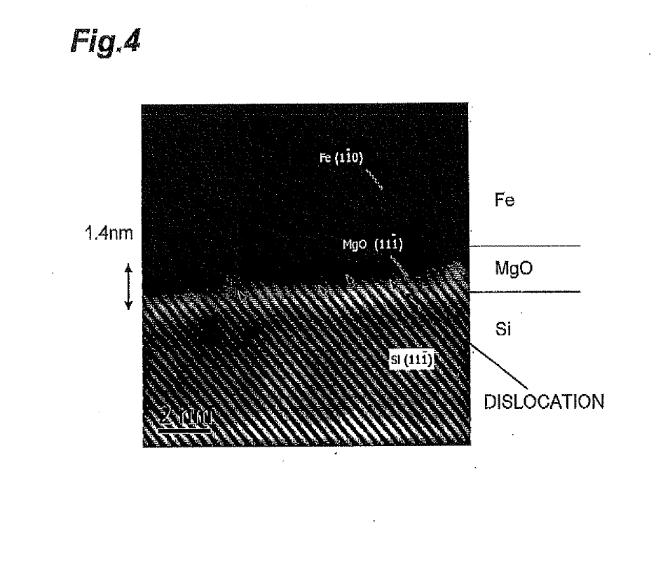

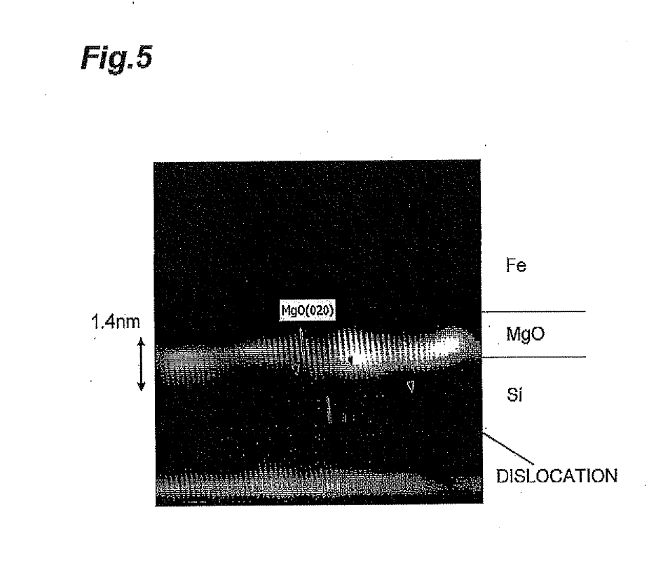

An interface state when Si is used as the semiconductor layer 3, single crystalline MgO is used as the tunnel insulating layer T1 (or T2), and Fe is used as the ferromagnetic layer 1 (or 2) was observed using a transmission electron microscope (TEM). FIGS. 4 and 5 show images in which a TEM image in the vicinity of an interface of an obtained device is subjected to a Fourier transform and only its specific reciprocal lattice component is subjected to inverse Fourier analysis. A wave number component is converted using a reciprocal lattice point and a [symbol] point in a Si [111] direction (k=(0, 0, 0)) in FIG. 4 and a reciprocal lattice point and a [symbol] point in a Si [110] direction in FIG. 5. An atomic arrangement is indicated by a line and extends linearly, and atoms are continuously arranged on the line.

Dimensions of devices of Comparative example and Example are as follows.

Separation distance between the first ferromagnetic metal layer and the first electrode: 50 μm

Separation distance between the second ferromagnetic metal layer and the second electrode: 50 μm

Separation distance between the first ferromagnetic metal layer and the second ferromagnetic metal layer: 500 nm

Thickness of the semiconductor layer 3: 100 nm

Thickness of the tunnel insulating layer: 1 nm

Current between the first electrode and the first ferromagnetic layer: 1 mA

Distance between a center of the first ferromagnetic layer and a center of the second ferromagnetic layer: 1.7 μm

FIG. 4 is a diagram showing an inverse Fourier TEM image of an Fe/MgO/Si stack (Comparative example).

In Comparative example, a SOI substrate (semiconductor substrate 10={100} Si, insulating layer 11=SiO₂, and semiconductor layer 3={100} Si having a thickness of 100 nm) was first prepared. Phosphorus (P) ions were injected as impurities into the semiconductor layer 3 at a concentration of 5×10¹⁹/cm³, and the SOT substrate was cleaned with acetone and isopropyl alcohol, and then an oxide film on a surface of the SOT substrate was removed using hydrofluoric acid. This substrate was then put into an MBE (molecular beam epitaxy) chamber, heated once at low temperature (300, 400, 500, 550, or 580° C.) for 60 minutes for annealing, and then MgO, Fe, and Ti films were formed at room temperature in that order. Here, Ti was a protection layer. FIG. 4 shows an inverse Fourier TEM image when annealing was performed at 300° C. (polarization rate P=0.0015).

The device in the non-local structure shown in FIG. 1 was then manufactured. In order to fix the magnetization of the ferromagnetic metal layers 1 and 2, the device was formed by vapor deposition using shape magnetic anisotropy and using Al as the materials of the electrode layers 1E and 2E and the electrodes 1M and 2M. {100} Si was used as the semiconductor layer 3, but an interface between Si and the grown MgO was a {100} surface, and a [110] direction of crystal of Si and MgO and a [100] direction of crystal of Fe were the same directions, which were parallel to the interface. A thickness of MgO was 1.4 nm. In FIG. 4, dislocation was observed in positions of triangular marks.

FIG. 5 is a diagram showing an inverse Fourier TEM image of an Fe/MgO/Si stack (Example).

In Example, an SOT substrate, which was the same as that in Comparative example, was first prepared. Phosphorus (P) ions were injected as impurities into the semiconductor layer 3 at a concentration of 5×10¹⁹(cm⁻³), the SOI substrate was cleaned with acetone and isopropyl alcohol, and then an oxide film on a surface of the SOI substrate was removed using hydrofluoric acid. This substrate was then put into an MBE (molecular beam epitaxy) chamber and heated once at high temperature (600, 620, 650, 680 or 700° C.) for 60 minutes for annealing, and then MgO, Fe, and Ti films were formed at room temperature in that order. Here, Ti is a protection layer. The device in the non-local structure shown in FIG. 1 was then manufactured using the same method as in Comparative example. FIG. 5 shows an inverse Fourier TEM image when annealing was performed at 700° C. (polarization rate P=0.35).

{100} Si was used as the semiconductor layer 3, but an interface between Si and the grown MgO was a {100}surface, and a [100] direction of Si crystal, a [110] direction of MgO crystal and a [100] direction of Fe crystal were the same directions, which were parallel to the interface. A thickness of MgO was 1.4 nm. In FIG. 5, dislocation was observed in positions of triangular marks.

From the above images, it can be seen that MgO is crystallized even in the vicinity of the interface. The interface may be referred to as a semi-coherent interface. In FIG. 4, there is dislocation in one layer about every five atom layers, and in FIG. 5, there is dislocation in one layer about every ten atom layers. If the Si/MgO interface is the semi-coherent interface, a bond between Si and O is broken in the position of the dislocation. Accordingly, unpaired electrons are left with dangling bonds.

Next, in samples of the above-described Comparative example (annealing temperature: 300° C. to 580° C.) and Example (annealing temperature 600° C. to 700° C.), area density of dangling bonds in an interface between the semiconductor layer 3 and the tunnel insulating layer T1 (T2) was measured using electron spin resonance (ESR) and a spin polarization rate P was obtained.

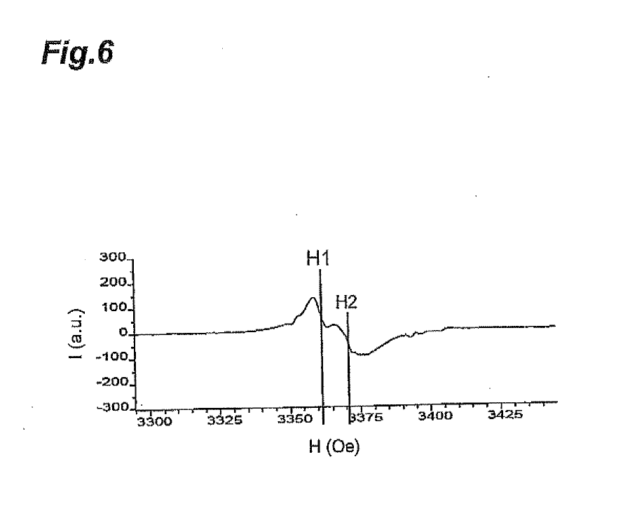

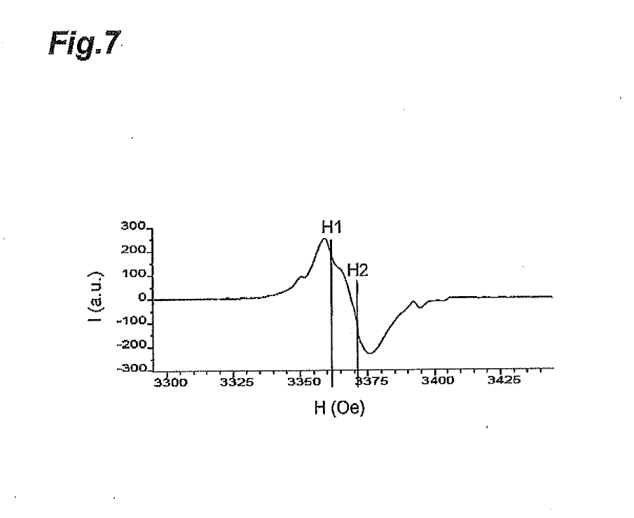

FIG. 6 is a graph showing an ESR spectrum (Comparative example: annealing temperature 550° C.), and FIG. 7 is a graph showing an ESR spectrum (Example: annealing temperature 700° C.). A horizontal axis indicates an applied external magnetic field H (Oe), and a vertical axis indicates an ESR spectral intensity I (a.u.). If the external magnetic field H is changed, the intensity I of an ESR signal is changed. In the ESR measurement, a g value is used. The g value is a unique value determined based on a frequency of a microwave applied from the outside and an intensity of a resonance magnetic field. For example, lattice defects can be identified by observing the spectrum and the g value. Power of the microwave is 200 μW and sample temperature upon spectrum measurement in FIGS. 6 and 7 is 8K.

In FIGS. 6 and 7, the g value in a magnetic field H1 is 2.0055, and the g value in a magnetic field H2 is 1.9996. When the g value is 2.0055, it can be considered that a bond (Si—O) between “O” in MgO and “Si” of the underlying semiconductor layer is broken, and a dangling bond is generated. The area density of the dangling bonds obtained using spectrum fitting is 4.8×10¹⁴/cm² in FIG. 6 and 1.0×10¹⁴/cm² in FIG. 7.

In the ESR spectrum, a P_{b} center has been observed. The P_{b} center includes a P_{b0} center in which one of four bonds extending from Si is broken and a triple bond between Si and Si occurs, and a P_{b1} center in which one bond is similarly broken and there are a double bond between Si and Si and a bond between Si and O. In the above spectrum, a peak is observed at the g value of 2.0055 in the magnetic field H1. This peak is caused by a typical P_{b} center, which is observed when the Si oxide film formed after cleaning using hydrofluoric acid is measured. This can be considered a result of reflecting bond breaking in the Si—O bond. A peak at the g value of 1.9996 in the magnetic field H2 may be considered a signal from electrons trapped in defects in MgO or SiO₂ and may be considered not to be involved in the dangling bonds.

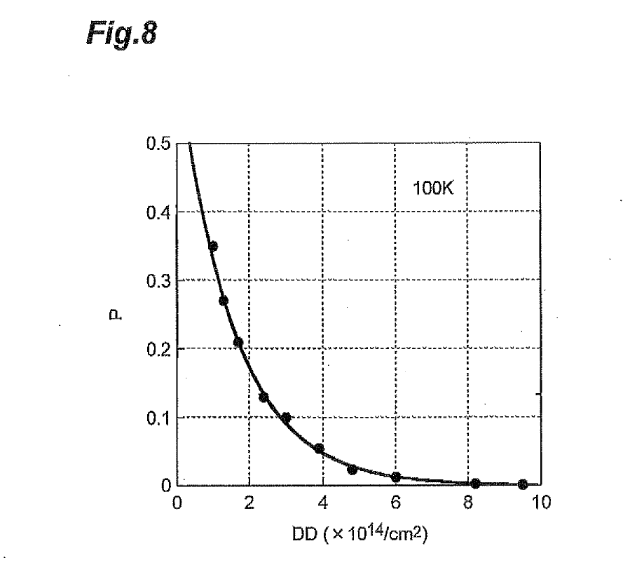

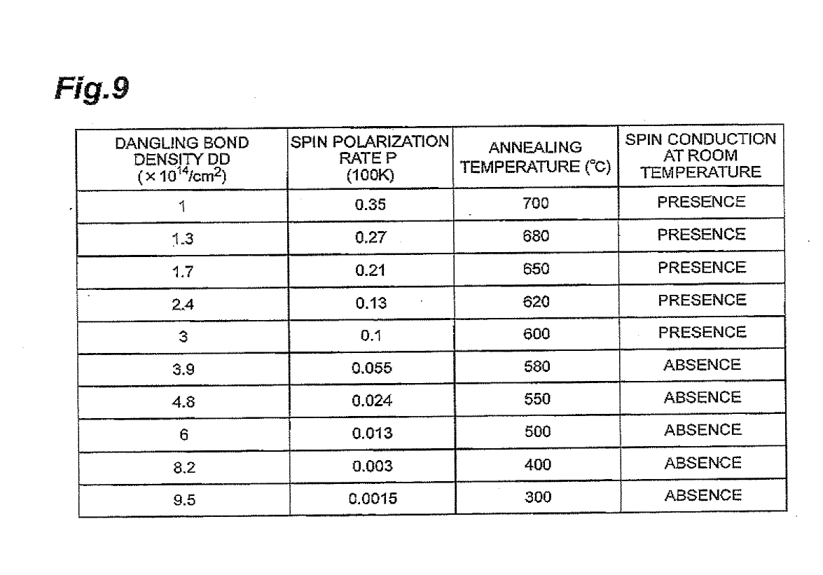

FIG. 8 is a graph (100K) showing a relationship between the area density DD (×10¹⁴/cm²) of the dangling bonds and the spin polarization rate P, and FIG. 9 is a table showing the area density DD (×10¹⁴/cm²) of the dangling bonds, the spin polarization rate P, the annealing temperature (° C.), and presence or absence of spin conduction at room temperature.

As shown in FIGS. 8 and 9, when the area density of the dangling bonds was equal to or less than 3×10¹⁴/cm², spin conduction was observed even at room temperature and the spin polarization rate P rapidly increased, and when the area density of the dangling bonds was 1×10¹⁴/cm², the spin polarization rate P of 0.35 could be obtained. In this case, the annealing temperature of the semiconductor layer 3 was 600° C. to 700° C. In Comparative example, the annealing temperature was 580° C. to 300° C., but the area density of the dangling bonds was 3.9×10¹⁴/cm² or more and the polarization rate P was low.

Disturbance of potential in the vicinity of the interface may be considered to increase as there are more dangling bonds, and it could be seen that the polarization rate P was attenuated exponentially with respect to the dangling bond density. In addition, according to the ESR measurement of the dangling bonds, it is considered that influence of Mg does not appear in nature of the interface and the Si—O bond has been broken. Accordingly, scattering of the electrons is expected to occur to the same extent as long as the crystal is similarly epitaxially grown even when the material is not MgO. A material with which the effect of the same extent can be obtained due to epitaxial growth on Si includes, for example, crystalline ZnO.

Considering a typical device, an output voltage V of 1 mV or more is required at an injection electron flow of 1 mA. Theoretically, the output voltage V is given as approximately (P²×λN×i)/(σS). A separation distance between the first and second ferromagnetic metal layers 1 and 2 is smaller than a spin diffusion length λN. For example, it is assumed that resistivity 1-σ of the semiconductor layer is 0.01 Ωcm, a sectional area S of the channel through which the spin flows is 1 μm² (=10 μm×0.1 μm), the spin diffusion length λN is 1 μm, and applied current i is 1 mA. In this case, if the output voltage V (1 mV or more) is in proportion to 0.1×P², the polarization rate P is, preferably, 0.1 or more. The dangling bond density is, correspondingly, 3×10¹⁴/cm² or less. It is preferable that the area density of the dangling bonds be lower but, in the above, the polarization rate was confirmed to be high when the area density of the dangling bonds was 1×10¹⁴/cm² or more.

Similarly, since spin scattering is suppressed, the polarization rate P is improved even when the spin is injected from the semiconductor layer into the ferromagnetic metal layer via the tunnel insulating layer.

As described above, when the single crystalline Si was used as the semiconductor layer and MgO was used as the tunnel insulating layer, the polarization rate P of 10% or more could be obtained. A maximum polarization rate P of 35% could be obtained.

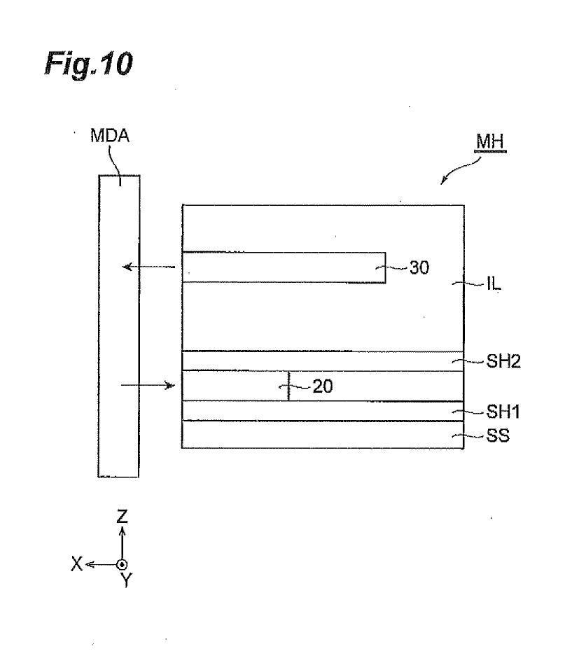

FIG. 10 is a diagram showing a longitudinal cross-sectional structure of a magnetic head including a spin device 20 as a magnetic sensor.

This magnetic sensor (spin device 20) is incorporated into the magnetic head MIT. The magnetic head M11 includes a support substrate SS such as AlTiC, a pair of magnetic shield layers SH1 and SH2 formed on the support substrate SS, and the spin device 20 arranged between the pair of magnetic shield layers SH1 and SH2. The spin device 20 functions as a magnetic sensor for detecting a magnetic field from a storage region of a magnetic recording medium MDA. The magnetic head MH includes an appropriate insulating layer IL of, for example, SiO₂ and a magnetic information writing device 30 is formed in the insulating layer IL. The writing device 30 can write magnetic information to the magnetic recording medium MDA. The writing device 30 is a device for generating a magnetic field when an electric current passes through its internal coil and is well known. The spin device 20 may be arranged so that an external magnetic field is introduced into the semiconductor layer 3 shown in FIG. 1. However, in the present example, the spin device 20 is set so that a flowing direction (Y axis direction) of the electron flow or the spin flow matches a track width direction of the magnetic recording medium MDA.

If the above-described spin device 20 is used as a magnetic sensor in a non-local structure, the spin device shown in FIG. 1 may be employed. The spin device 20 includes the first and second tunnel insulating layers T1 and T2 formed on the surface of the semiconductor layer 3, the ferromagnetic metal layers 1 and 2 respectively formed on the first and second tunnel insulating layers T1 and T2, and the pair of electrodes 1M and 2M formed of a non-magnetic metal on the semiconductor layer 3.

If the above-described spin device 20 is used as a magnetoresistance effect magnetic sensor, the electrodes 1M and 2M in FIG. 1 are unnecessary, and the arrangement when the spin device 20 is incorporated into the magnetic head is set so that the flowing direction (Y axis direction) of the electron flow matches the track width direction of the magnetic recording medium MDA.

Since the above-described magnetic sensor has a high polarization rate, the magnetic sensor can detect an external magnetic field with high accuracy.

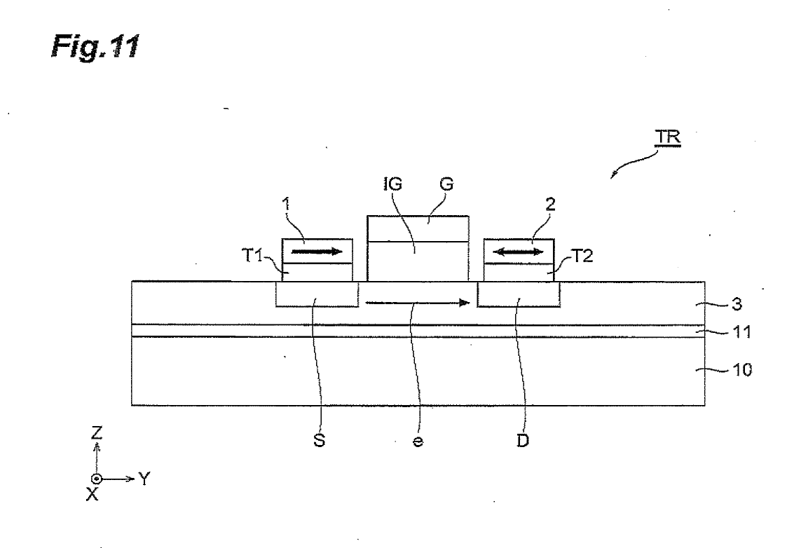

FIG. 11 is a diagram showing a longitudinal cross-sectional structure of a spin FET including the above-described spin device 20.

This spin FET (TR) similarly includes main parts (substrate 10, insulating layer 11, semiconductor layer 3, first and second tunnel insulating layers T1 and T2, and ferromagnetic metal layers 1 and 2) of the above-described spin device 20. Here, the semiconductor layer 3 is set to a P type, and a source region S and a drain region D are formed by adding N-type impurities to the semiconductor layer 3. The above-described tunnel insulating layers T1 and T2 are formed on the source region S and the drain region D of the semiconductor layer 3, respectively. The ferromagnetic metal layers 1 and 2 are formed on the tunnel insulating layers T1 and T2, respectively. A gate electrode G is formed on a region between the first and second ferromagnetic metal layers 1 and 2 via a gate insulating film 1G in order to control a potential of the semiconductor layer 3 between the first and second ferromagnetic metal layers 1 and 2. An amount of a spin-polarized electron flow e flowing from the source S to the drain D can be controlled by a gate voltage. The second ferromagnetic metal layer 2 is a free layer, and a magnetization direction of the second ferromagnetic metal layer 2 can be controlled by an external magnetic field or spin injection structure, which is not shown. An amount of electrons flowing into the free layer can be controlled by controlling the magnetization direction of the free layer.

As described above, the spin. FET includes the tunnel insulating layers T1 and T2 formed on the surface of the semiconductor layer 3, and the ferromagnetic metal layers 1 and 2 formed on the tunnel insulating layers. However, since the spin polarization rate is high, the spin can flow into the free layer with high accuracy according to the magnetization direction of the free layer, and a high-accuracy operation can be performed.

What is clamed is:

1. A spin device comprising:
a semiconductor layer formed of single crystalline Si;
a first tunnel insulating layer formed on a surface of the semiconductor layer, the first tunnel insulating layer being crystalline; and
a first ferromagnetic metal layer formed on the first tunnel insulating layer,
wherein an area density of dangling bonds in an interface between the semiconductor layer and the first tunnel insulating layer is 3×10¹⁴/cm² or less.

2. The spin device according to claim 1, wherein the area density of the dangling bonds is 1×10¹⁴/cm² or more.

3. The spin device according to claim 1, wherein the first tunnel insulating layer includes MgO.

4. A magnetic sensor comprising:
the spin device according to claim 1;
a second tunnel insulating layer formed on the surface of the semiconductor layer;
a second ferromagnetic metal layer formed on the second tunnel insulating layer; and
a pair of electrodes formed of a non-magnetic metal on the semiconductor layer.

5. A spin FET comprising:
the spin device according to claim 1;
a second tunnel insulating layer formed on the surface of the semiconductor layer;
a second ferromagnetic metal layer formed on the second tunnel insulating layer; and
a gate electrode for controlling a potential of the semiconductor layer between the first and second ferromagnetic metal layers.
